(19) United States
(12) Patent Application Publication
(10) Pub. No.: US 2007/0029674 A1
(43) Pub. Date: Feb. 8, 2007

(54) Board-on-chip package and stack package using the same

(76) Inventors: Dong-Kil Shin, Gyeonggi-do (KR); Se-Young Yang, Daejeon Metropolitan City (KR); Shin Kim, Chungcheongnam-do (KR); Wang-Ju Lee, Chungcheongnam-do (KR)

Correspondence Address: MARGER JOHNSON & MCCOLLOM, P.C., 210 SW MORRISON STREET, SUITE 400, PORTLAND, OR, 97204, US

(21) Appl. No.: 11/375,760

(22) Filed: Mar. 14, 2006

(30) Foreign Application Priority Data
Aug. 8, 2005 (KR) 2005-72388

(51) Int. Cl. H01L 23/48

(52) U.S. Cl. 257/738

(57) ABSTRACT

Provided is a board-on-chip package and stack package using the same to reduce the likelihood that bonding wires in an encapsulant may be damaged due to mechanical stresses applied during a package stacking process. A semiconductor package may have a spacer provided along the opposing sides of an encapsulant. The spacer may be spaced away from bonding wires embedded in the encapsulant. The height of the spacer may be greater than the height of the encapsulated bonding wire from the bottom surface of the semiconductor package. The spacer may be formed of a bar or a protrusion. In a stack package using the semiconductor package, the spacer may be provided between a semiconductor chip of a lower semiconductor package and an encapsulant of an upper semiconductor package.

### CROSS REFERENCE TO RELATED APPLICATIONS

This U.S. non-provisional application claims benefit of priority under 35 U.S.C. § 119 from Korean Patent Application No. 2005-72388, filed on Aug. 8, 2005, the entire contents of which are incorporated herein by reference.

### BACKGROUND OF THE INVENTION

1. Field of the Invention

The present invention relates to a semiconductor package and a stack package using the semiconductor package, and more particularly, to a board-on-chip (BOC) package and a stack package using the BOC package.

2. Description of the Related Art

The electronic industry is continually seeking methods, techniques, and designs that will result in the manufacture of electronic products that are smaller, lighter, faster, more efficient, operate at higher speeds, provide multiple functions and/or result in improved performance, at an effective cost. One of the methods that has been used for attaining such goals is a chip scale packaging technique. The chip scale packaging technique may provide chip scale packages or chip size packages (CSPs).

Semiconductor packages that are lighter, smaller, thinner, and can contain a large number of semiconductor chips continue to be desirable. In order to increase the semiconductor chip capacity while decreasing package size, technology that can arrange cells more densely in a semiconductor chip is necessary. One solution has been 3-D type semiconductor packaging technologies based on stacking semiconductor chips or semiconductor packages.

Examples of 3-D stack chip packages include a package having a plurality of semiconductor chips stacked on each other, thereby achieving denser, more compact semiconductor packages. Unfortunately, 3-D type semiconductor packaging technologies based on chip stacking have negatively impacted production rates. For example, faulty chips can dramatically impact production rates because a single faulty chip among a stack of semiconductor chips will cause the whole stack of semiconductor chips to be faulty and non-repairable. In addition, chips are typically unable to be validated until they are included in a package.

One solution to the faulty stack problem has been to stack packages instead of chips. Although a stack of packages is thicker than a stack of chips, since each chip includes its own package, a stack of packages has the advantage that each package may be individually validated, thus avoiding the reliability and production rate problems caused by chip stacking.

FIG. 1 is a cross-sectional view of a conventional stack package 100 having BOC packages 10 including a lower package 10a and an upper package 10b.

The BOC package 10 is a fan-out type semiconductor package and may include a circuit substrate 20 having a top surface 21 including a chip mounting area and a bottom surface 23 with solder bumps 60 arranged along the edges thereof. A semiconductor chip 30 may have chip pads 31 arranged in the center thereof. The circuit substrate 20 may have a central window 25, through which the chip pads 31 may be exposed. Bonding wires 40 may connect the chip pads 31 to the circuit substrate 20 through the central window 25. An encapsulant 50 may seal the chip pads 31 and the bonding wires 40 to protect them from the external environment. The solder bumps 60 of the upper package 10b may be used in stacking the upper package 10b on the lower package 10a, and the solder bumps 60 of the lower package 10a may be used in mounting the stack package 100 on a motherboard or another BOC package.

The semiconductor chip 30 may be exposed to the external environment. The height of the solder bumps 60 may be greater than the height of the encapsulant 50 from the bottom surface 23 of the circuit substrate 20.

A package stacking process may use a solder bonding process. For example, flux may be applied to the solder bumps 60 of the upper package 10b, and the upper package 10b may be mounted on the lower package 10a such that the solder bumps 60 of the upper package 10b are arranged on the circuit substrate 20 of the lower package 10a. The solder bumps 60 of the upper package 10b may be melted so as to be connected to the circuit substrate 20 of the lower package 10a.

For the thin stack package 100, the encapsulant 50 of the upper package 10b may be arranged close to the semiconductor chip 30 of the lower package 10a.

FIGS. 2 and 3 are cross-sectional views illustrating examples of damage to the bonding wires 40 of the stack package 100.

Referring to FIG. 2, while the solder bumps 60 are melted during the solder bonding process, the lower and upper package 10a and 10b may draw to each other due to the surface tension of solder. Thereby the encapsulant 50 of the upper package 10b may be pressed by the semiconductor chip 30 of the lower package 10a. Moreover, the entire surface of the encapsulant 50 may be closely adhered to the back surface of the semiconductor chip 30 of the lower package 10a. Thereby the encapsulant 50 may be under the influence of pressure, thus resulting in damage to the bonding wires 40 embedded in the encapsulant 50.

Referring to FIG. 3, flux 62 used in the solder bonding process may gather between the semiconductor chip 30 of the lower package 10a and the encapsulant 50 of the upper package 10b by a capillary phenomenon. Since the flux 62 has adhesive strength, a liposoluble flux may have a relatively strong lipsolibality. Thus, when the melted solder bumps 60 contract as they are solidified, the distance between the lower package 10a and the upper package 10b may increase. The flux 62 interposed between the semiconductor chip 30 of the lower package 10a and the encapsulant 50 of the upper package 10b may further draw the encapsulant 50 downward. As a result, tension may be applied to the bonding wires 40 in the encapsulant 50, thus damaging the bonding wires 40.

In addition, during a reliability test process involving heat and humidity, the BOC packages 10 may repetitively contract and expand, resulting in the semiconductor chip 30 of the lower package 10a repetitively applying mechanical stresses to the encapsulant 50 of the upper package 10b, and thereby damaging the bonding wires 40 in the encapsulant.

In order to solve these problems, the upper package 10b may be stacked further above the lower package to provide more space between the packages. However, by increasing the space between the semiconductor chip 30 of the lower package 10a and the encapsulant 50 of the upper package 10b the overall thickness of the stack package 100 will be increased.

Alternatively, the encapsulant 50 may be formed from an epoxy molding compound instead of a silicon molding compound. The epoxy molding compound may reduce the likelihood that the bonding wires 40 in the encapsulant 50 will be damaged due to mechanical stresses. However, the epoxy molding compound may also have a lower modulus of elasticity than the silicon molding compound. As a result, the epoxy molding compound may insufficiently absorb these mechanical stresses which in turn may result in a difference in the coefficients of thermal expansion between a semiconductor chip and a circuit substrate, thereby resulting in warpage of the BOC package. Therefore, the use of an epoxy molding compound may be unacceptable for the encapsulant 50.

### SUMMARY OF THE INVENTION

Embodiments of the present invention are directed to providing a stack package to reduce the likelihood that bonding wires in an encapsulant may be damaged due to mechanical stresses applied during a package stacking process.

According to an example embodiment of the present invention, a semiconductor package may include a circuit substrate having a top surface, a bottom surface, and a central window. A semiconductor chip may be provided on the top surface of the circuit substrate, and have an active surface with chip pads exposed through the central window, and a back surface opposite to the active surface. Bonding wires may connect the chip pads of the semiconductor chip to the circuit substrate through the central window. An encapsulant may seal the chip pads and the bonding wires. Solder bumps may be provided on the bottom surface of the circuit substrate. A spacer may be arranged along opposing sides of the encapsulant. The height of the spacer may be greater than the height of the bonding wire from the bottom surface of the circuit substrate.

### BRIEF DESCRIPTION OF THE DRAWINGS

Example, non-limiting embodiments of the present invention will be readily understood with reference to the following detailed description thereof provided in conjunction with the accompanying drawings, wherein like reference numerals designate like structural elements.

FIG. 1 is a cross-sectional view of a conventional stack package using BOC packages.

FIGS. 2 and 3 are cross-sectional views of a conventional stack package illustrating examples of bonding wire damage in the stack package.

FIG. 4 is a plan view of a BOC package in accordance with an example embodiment of the present invention.

FIG. 5 is a cross-sectional view taken along the line I-I in FIG. 4.

FIG. 6 is a plan view of a stack package using the BOC package embodiments illustrated in FIG. 4.

FIG. 7 is a plan view of a BOC package in accordance with another example embodiment of the present invention.

FIG. 8 is a plan view of a BOC package in accordance with another example embodiment of the present invention.

FIG. 9 is a cross-sectional view taken along the line II-II in FIG. 8.

FIG. 10 is a cross-sectional view of a stack package using the BOC package embodiments illustrated in FIG. 8.

FIG. 11 is a plan view of a BOC package in accordance with another example embodiment of the present invention.

FIG. 12 is a plan view of a BOC package in accordance with another example embodiment of the present invention.

FIG. 13 is a plan view of a BOC package in accordance with another example embodiment of the present invention.

FIG. 14 is a cross-sectional view taken along the line III-III in FIG. 13.

FIG. 15 is a cross-sectional view of a stack package using the BOC package embodiments illustrated in FIG. 13.

FIG. 16 is a plan view of a BOC package in accordance with another example embodiment of the present invention.

FIG. 17 is a cross-sectional view taken along the line IV-IV in FIG. 16.

FIG. 18 is a cross-sectional view of a stack package using the BOC package embodiments illustrated in FIG. 13.

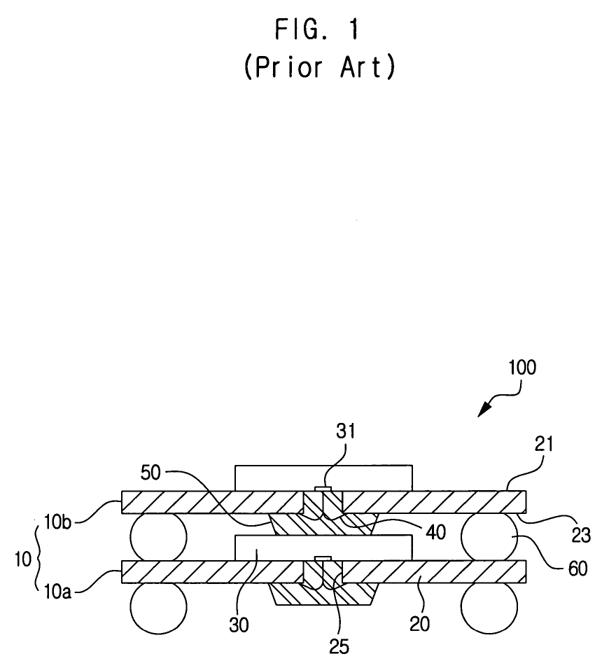

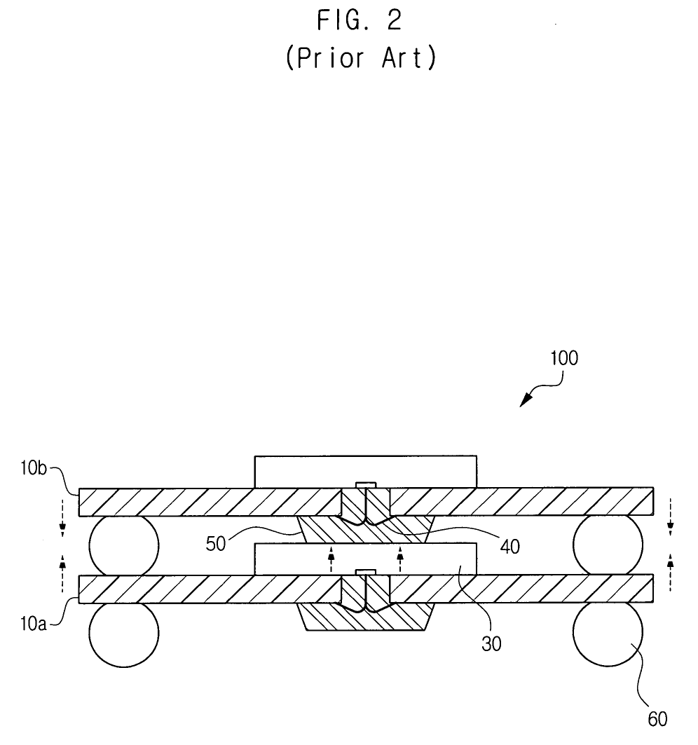

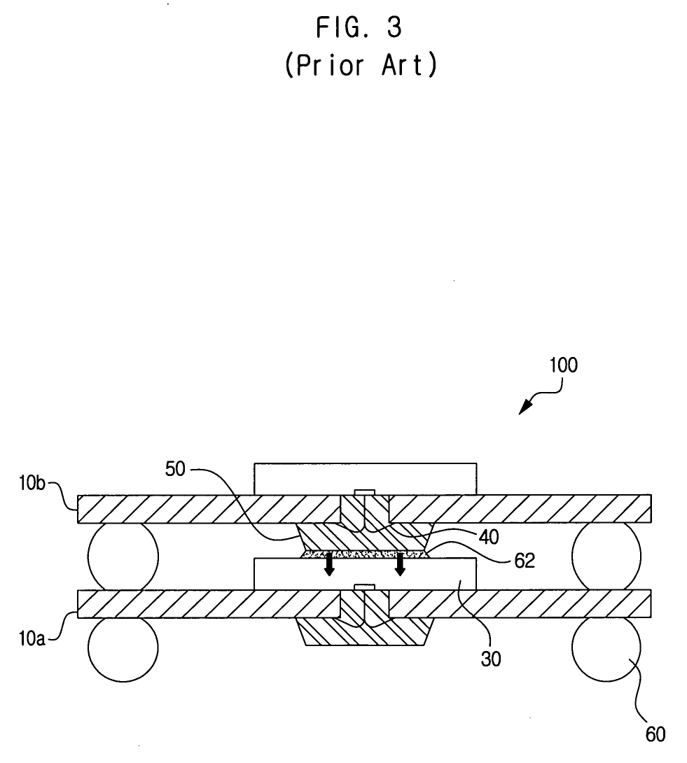

The drawings are provided for illustrative purposes only and are not drawn to scale. The spatial relationships and relative sizing of the elements illustrated in the various embodiments may have been reduced, expanded or rearranged to improve the clarity of the figure with respect to the corresponding description. The figures, therefore, should not be interpreted as accurately reflecting the relative sizing or positioning of the corresponding structural elements that could be encompassed by an actual device manufactured according to the example, non-limiting embodiments of the invention.

### DETAILED DESCRIPTION OF THE INVENTION

Example, non-limiting embodiments of the present invention will be described more fully with reference to the accompanying drawings. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. The principles and features of this invention may be employed in varied and numerous embodiments without departing from the scope of the invention.

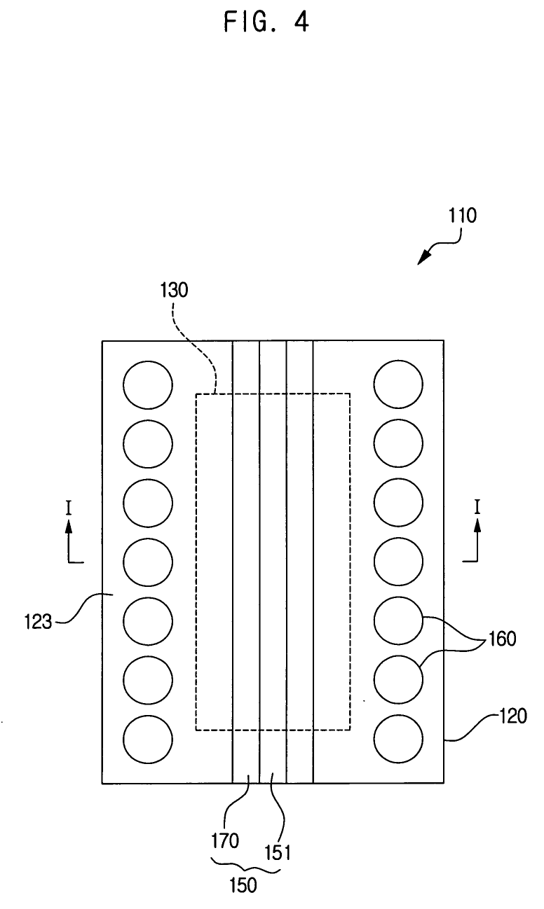

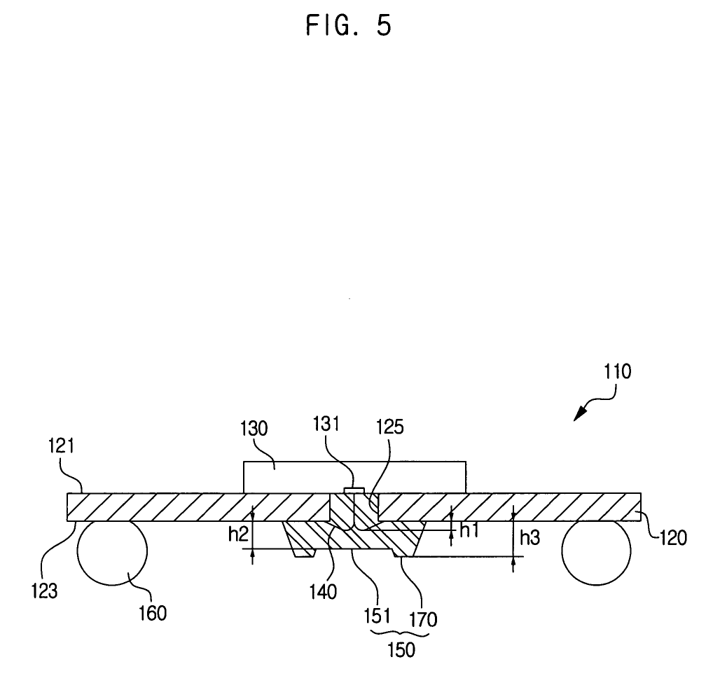

FIG. 4 is a plan view of a BOC package 110 in accordance with an example embodiment of the present invention. FIG. 5 is a cross-sectional view taken along the line I-I in FIG. 4.

Referring to FIGS. 4 and 5, the BOC package 110 is a fan-out type semiconductor package and may include a circuit substrate 120 having a top surface 121 having a chip mounting area and a bottom surface 123 with solder bumps 160 arranged along the edges thereof. A semiconductor chip 130 may be mounted on the top surface 121 of the circuit substrate 120 and have chip pads 131 arranged in the center thereof. The circuit substrate 120 may have a central window 125, through which the chip pads 131 may be exposed. Bonding wires 140 may connect the chip pads 131 to the circuit substrate 120 through the central window 125. An encapsulant 150 may seal the chip pads 131 and the bonding wires 140 to protect them from the external environment. The encapsulant 150 may be formed from a silicon molding compound. The solder bumps 160 may serve as external connection terminals.

The BOC package 110 may further include a spacer 170. The spacer 170 may be provided along the opposing sides of the encapsulant 150. The height of the spacer 170 may be greater than the height of the encapsulant 150 from the bottom surface 123 of the circuit substrate 120. The encapsulant 150 may include a first encapsulant 151 sealing the bonding wires 140 and a second encapsulant, for example the spacer 170, formed integrally with the first encapsulant 151. The height (h2) of the first encapsulant 151 from the bottom surface 123 may be greater than the height (h1) of the bonding wires 140 from the bottom surface 123 so that the first encapsulant 151 may seal the bonding wires 140. The height (h3) of the spacer 170 may be greater than the height (h2) of the first encapsulant 151 from the bottom surface 123. The spacer 170 may also be formed of a bar along the longer sides of the encapsulant 150.

The spacer 170 may be arranged corresponding to the bottom surface 123 of the circuit substrate 120 outside the central window 125. Preferably, the spacer 170 may be arranged so as to be spaced away from the bonding wires 170 so that the spacer 170 may sustain pressure applied to the encapsulant 150 without damaging the bonding wires 140.

The encapsulant 150 including the spacer 170 may be formed by a dotting method using a syringe. At least one syringe may be used. For example, a liquid molding compound contained in the syringe may be supplied to the central window 125 using a dotting method, thereby forming the first encapsulant 151. Subsequently, the spacer 170 may be formed in the same manner as the first encapsulant 151. Alternatively, three syringes may be used to simultaneously form the first encapsulant 151 and the spacer 170. In this case, a relatively smaller quantity of the liquid molding compound may be supplied to the syringes for the spacer 170. While the syringes may move, the liquid molding compound for the spacer 170 may run to the central window 125. Therefore, the dotting quantity of the liquid molding compound may be controlled.

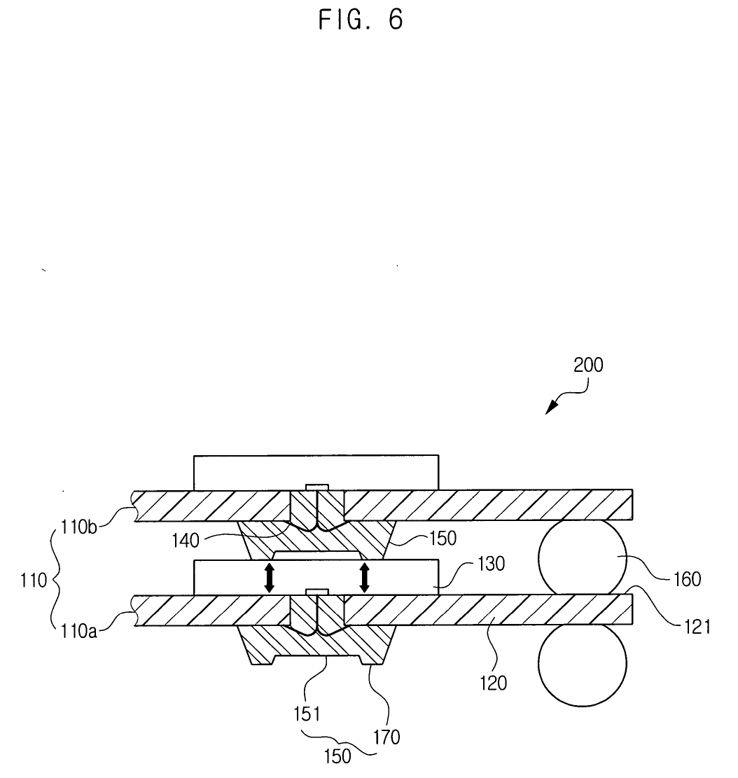

FIG. 6 is a plan view of a stack package 200 using the BOC package embodiments 110 illustrated in FIG. 4.

Referring to FIG. 6, the stack package 200 may comprise BOC packages 110 including a lower package 110a and an upper package 110b. The upper package 110b may be stacked on the lower package 110a using the solder bumps 160 of the upper package 110b. The solder bumps 160 of the lower package 110a may be used to mount the stack package 200 on a motherboard or another BOC package.

The upper package 110b may be stacked on the lower package 110a such that the spacer 170 of the upper package 110b may be located near the back surface of the semiconductor chip 130 of the lower package 110a. The spacer 170 of the upper package 110b may also be in contact with the back surface of the semiconductor chip 130 of the lower package 110a. The spacer 170 may reduce the likelihood that applied mechanical stresses will damage the bonding wires 140 in the encapsulant 150.

Specifically, during the solder bonding process the lower package 110a and the upper package 110b may draw toward each other, while the solder bumps 160 are being melted. At this time, the semiconductor chip 130 of the lower package 110a may apply pressure to the upper package 110b. The spacer 170, spaced away from the bonding wires 140 in the first encapsulant 151, may confront the pressure first, thereby preventing the pressure from being applied to, and thus damaging, the bonding wires 140.

The flux used in the solder bonding process, which may be applied to the solder bumps 160 of the upper package 110b may run to the surfaces of the lower package 110a and the upper package 110b and consequently gather between the spacer 170 of the upper package 10b and the semiconductor chip 130 of the lower package 10a. When the melted solder bumps 160 contract while being solidified, the distance between the lower package 110a and the upper package 110b may increase. The flux interposed between the spacer 170 and the semiconductor chip 130 may draw the spacer 170 downward. The spacer 170 spaced away from the first encapsulant 151 may again confront the tension, thereby preventing the tension from being applied to the first encapsulant 151.

After a package stacking process, a reliability test process involving heat and humidity may be performed on the resultant stack package 100. The heat and humidity involved in the reliability test process may repetitively apply mechanical stresses, such as contractions and expansions, to the stack package 110. The spacer 170 of the example embodiment of the present invention may absorb these mechanical stresses, thereby reducing the likelihood that the mechanical stresses will damage the bonding wires 140.

Although this example embodiment shows the stack package 200 comprising two BOC packages, the stack package 200 may comprise three or more BOC packages.

In this example embodiment, the spacer 170 is formed as a continuous bar. However, as some of the embodiments below demonstrate, the spacer may be formed in a variety of configurations without departing from the spirit and scope of the present invention.

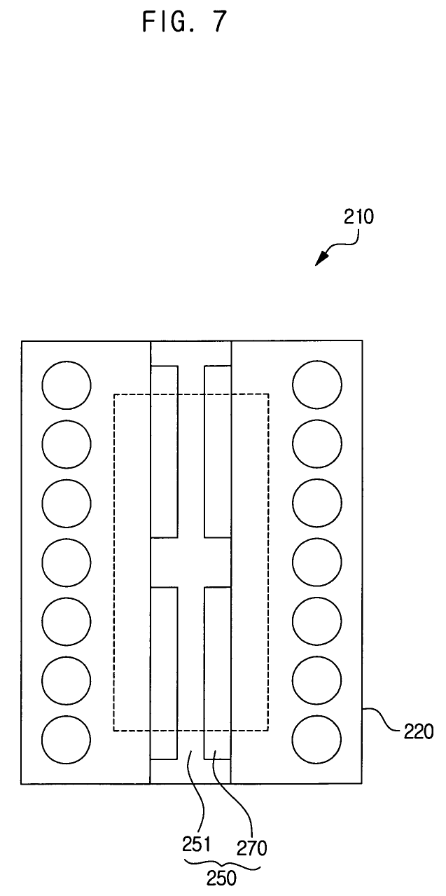

FIG. 7 is a plan view of a BOC package 210 in accordance with another example embodiment of the present invention.

Referring to FIG. 7, the BOC package 210 may have a similar structure as the BOC package 110, except that the spacer is formed to be a discontinuous bar. In the embodiment illustrated in FIG. 7, the spacer 270 includes two spacers arranged at each side of a first encapsulant 251, wherein each spacer 270 includes two separate bars. Although this embodiment shows the spacers separated into two separate bars, it should be understood that the spacer may be separated in to three or more separate bars.

Since the resultant stack package of this example embodiment has an otherwise similar structure to the stack package 200, further detailed descriptions will be omitted.

Although the above example embodiments show the spacer formed integrally with the first encapsulant, the spacer may also be formed separately from the first encapsulant.

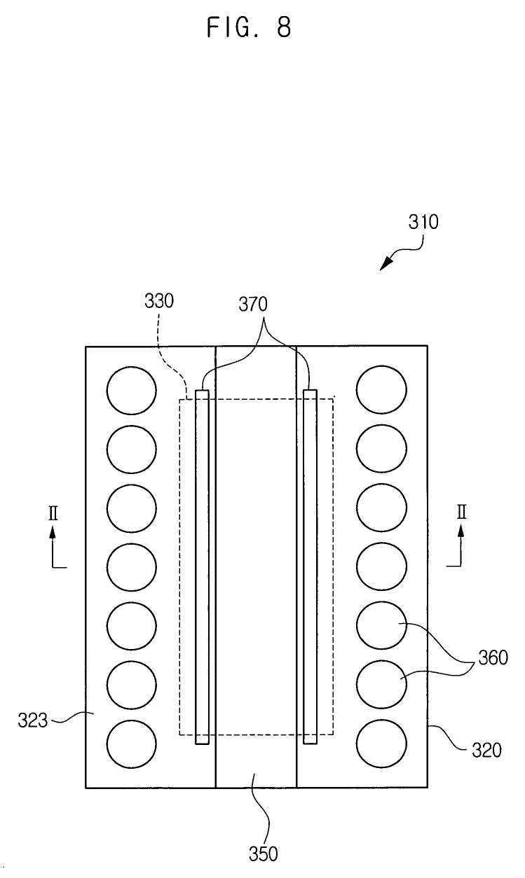

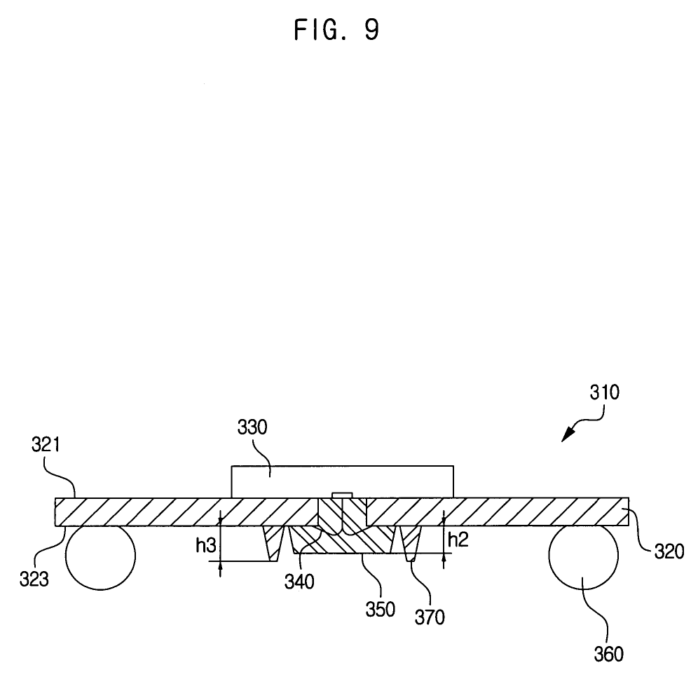

FIG. 8 is a plan view of a BOC package 310 in accordance with another example embodiment of the present invention. FIG. 9 is a cross-sectional view taken along the line II-II in FIG. 8.

Referring to FIGS. 8 and 9, the BOC package 310 may include a circuit substrate 320 having a top surface 321 including a chip mounting area and a bottom surface 323 with solder bumps 360. The circuit substrate 320 may have an encapsulant 350 and a spacer 370.

The spacer 370 may be formed at opposing sides of the encapsulant 350, so as to be separate from the encapsulant 350. The height (h3) of the spacer 370 may be greater than the height (h2) of the encapsulant 370 from the bottom surface 323 of the circuit substrate 320. The spacer 370 may be formed of a continuous bar having a predetermined length. The length of the spacer 370 may correspond to the length of the longer side of the encapsulant 350.

The spacer 370 may be provided on the bottom surface 323 of the circuit substrate 310 corresponding to the chip mounting area. However, the spacer 370 may also be arranged on the bottom surface 323 of the circuit substrate so as to be outside the chip mounting area, for example between the bottom surface 323 corresponding to the mounting area and a solder bump attaching area. In this embodiment, the spacer should be formed to have a sufficient height so as to contact the top surface of a lower package for package stacking before the encapsulant 350 contracts the chip of a lower package. Otherwise, the spacer may be caught between a semiconductor chip of a lower package and the solder bumps of an upper package during a package stacking process, thereby damaging the spacer. However, it is preferable to arrange the spacer 370 on the bottom surface 323 of the circuit substrate 310 corresponding to the chip mounting area.

To effectively prevent the contact between the encapsulant 350 of an upper package and the semiconductor chip of a lower package, the spacer 370 may be arranged near each side of the encapsulant 250.

The spacer 370 may be formed from a similar silicon molding compound as the encapsulant 350, or a nonconductive material. For example, the spacer 370 may be formed by printing a liquid epoxy resin or attaching a nonconductive film. The nonconductive film may include a polyimide tape.

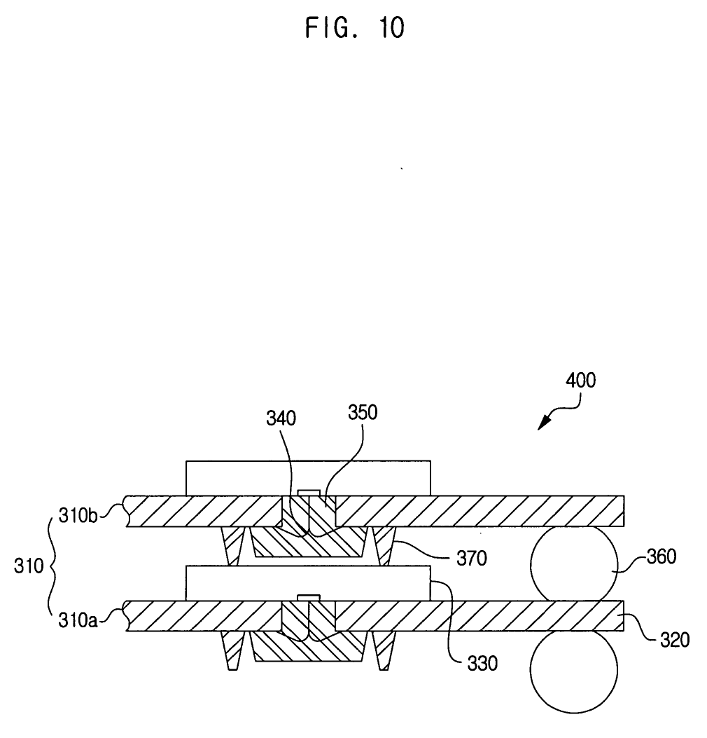

FIG. 10 is a cross-sectional view of a stack package 400 using the BOC package embodiments 310 illustrated in FIG. 8.

Referring to FIG. 10, the stack package 400 may comprise a lower package 310a and an upper package 310b stacked on the lower package 310a using solder bumps 360.

Although the spacer 370 of this example embodiment is separated from the encapsulant 350, the spacer 370 may have the same function as the spacer 170 illustrated in FIG. 5, in that the spacer 370 of the upper package 310b may absorb pressure and/or tension so as to prevent the pressure and/or tension on the encapsulant 350, and thereby prevent mechanical stresses from being applied to the bonding wires 340 in the encapsulant 350.

In this example embodiment, the spacer 370 may be formed of a continuous bar. In alternative embodiments, the spacer may be formed of various shapes.

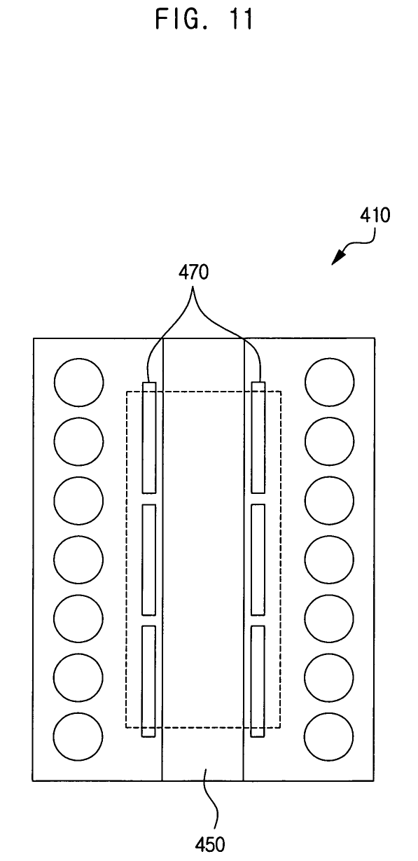

FIG. 11 is a plan view of a BOC package 410 in accordance with another example embodiment of the present invention.

Referring to FIG. 11, the BOC package 410 may have the same structure as the BOC package 310 illustrated in FIG. 10, except that the BOC package 410 has a spacer 470 formed of a discontinuous bar on both sides of the encapsulant 450.

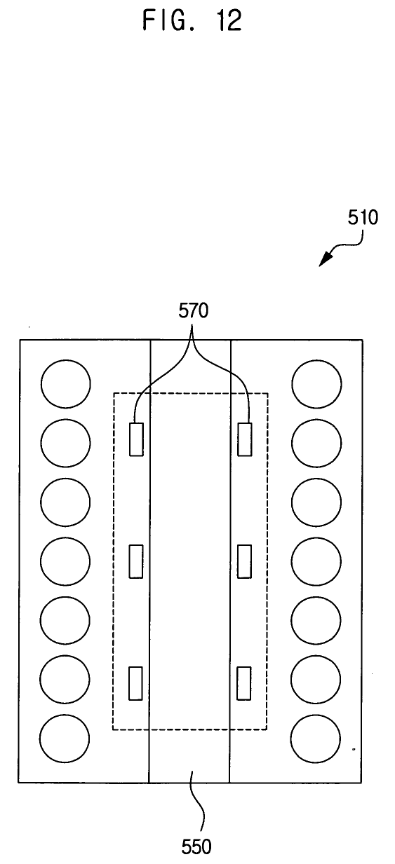

FIG. 12 is a plan view of a BOC package 510 in accordance with another example embodiment of the present invention.

Referring to FIG. 12, the BOC package 510 may have the same structure as the BOC package 310 illustrated in FIG. 10, except that the BOC package 510 has a spacer 570 formed in a series of protrusions on both sides of the encapsulant 550.

In the above example embodiments, the spacer may be provided on the bottom surface of the circuit substrate. However, in alternative embodiments, the spacer may be provided on the semiconductor chip of the lower package.

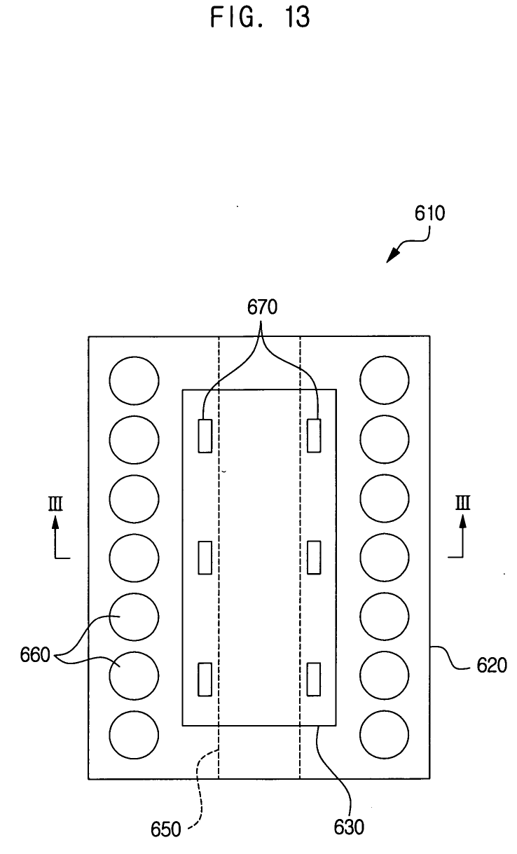

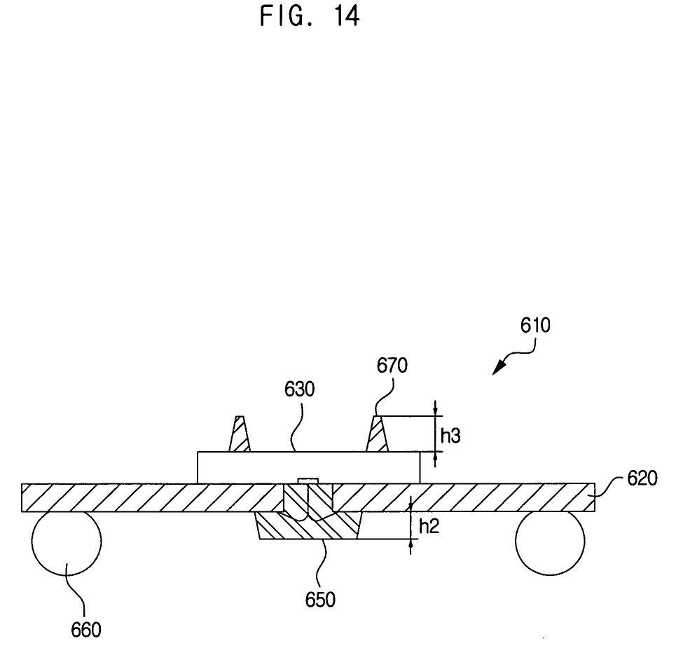

FIG. 13 is a plan view of a BOC package 610 in accordance with another example embodiment of the present invention. FIG. 14 is a cross-sectional view taken along the line III-III in FIG. 13.

Referring to FIGS. 13 and 14, the BOC package 610 may include a circuit substrate 620 having an encapsulant 650 and a semiconductor chip 630 having a back surface. A spacer 670 may be arranged on the back surface of the semiconductor chip 630 corresponding to the opposing sides of the encapsulant 650. The height (h3) of the spacer 670 may be greater than the height (h2) of the encapsulant 650 from the bottom surface of the circuit substrate 620.

In this example embodiment, the spacer 670 may be formed in a series of protrusions. In alternative embodiment, the spacer 670 may be formed as a continuous bar as shown in FIG. 8 or of a discontinuous bar as shown in FIG. 11.

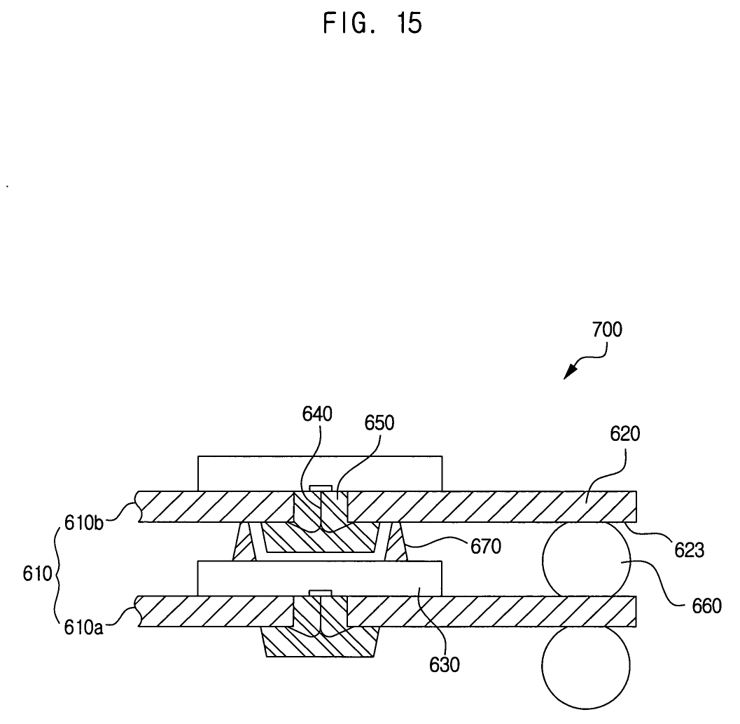

FIG. 15 is a cross-sectional view of a stack package 700 using the BOC package embodiments 610 illustrated in FIG. 13.

Referring to FIG. 15, the stack package 700 may comprise a lower package 610a and an upper package 610b stacked on the lower package 610a using solder bumps 660. The spacer 670 may be arranged on the back surface of the semiconductor chip 630 of the lower package 610a near the encapsulant 650 of the upper package 610b.

Since the height (h3) of the spacer 670 is greater than the height (h2) of the encapsulant 650 of the upper package 610b, the encapsulant 650 is not in contact with the back surface of the semiconductor chip 630 of the lower package 610a.

The stack package 700 may have the same structure as the stack package 400 illustrated in FIG. 10, in that the spacer 670 may be interposed between the semiconductor chip 630 of the lower package 610a and the bottom surface 623 of the circuit substrate 620 of the upper package 610b.

For a thin stack package, an uppermost package may use a BOC package without a spacer.

In this example embodiment, the spacer 670 may be arranged on the back surface of the semiconductor chip 630, spaced away from the encapsulant 650. However, in alternative embodiments, the spacer may be arranged on the back surface of the semiconductor chip corresponding to the encapsulant.

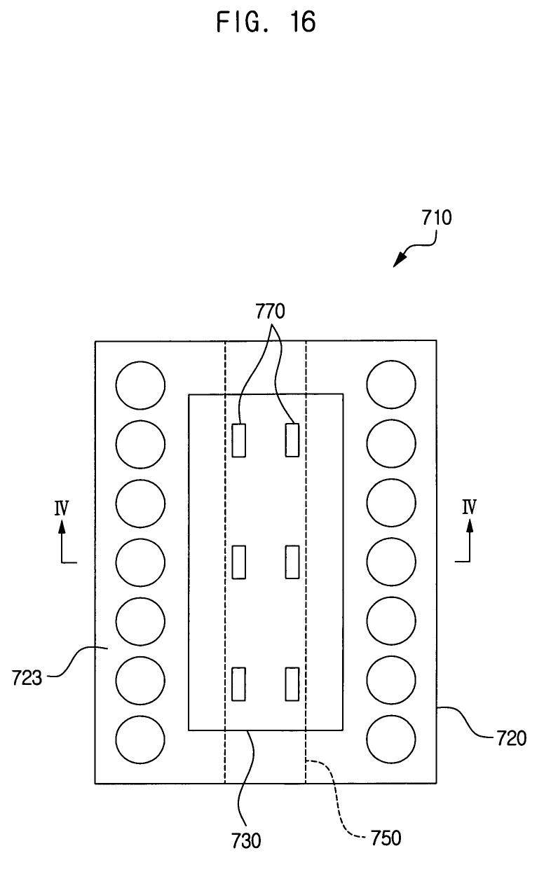

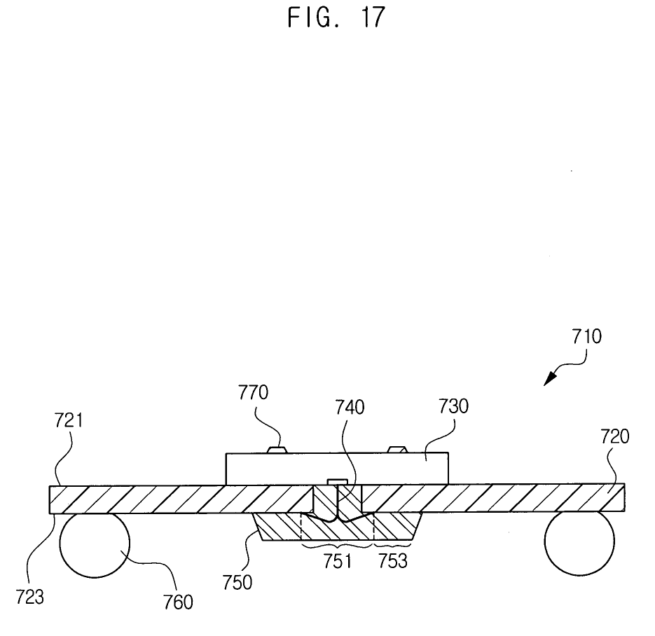

FIG. 16 is a plan view of a BOC package 710 in accordance with another example embodiment of the present invention. FIG. 17 is a cross-sectional view taken along the line IV-IV in FIG. 16.

Referring to FIGS. 16 and 17, the BOC package 710 may include a circuit substrate 720 having a bottom surface 723 with solder bumps 760 and a semiconductor chip 730 having a back surface. An encapsulant 750 may seal bonding wires 740. A spacer 770 may be provided on the back surface of the semiconductor chip 730.

The encapsulant 750 may include a first encapsulant 751 sealing the bonding wires 740, and a second encapsulant 753 formed integrally with the first encapsulant 751 and on the bottom surface 723 of the circuit substrate 720. The height of the first encapsulant 751 from the bottom surface 723 of the circuit substrate 720 may be equal to the height of the second encapsulant 753. The second encapsulant 753 may extend from the first encapsulant 750 to the bottom surface 723 of the circuit substrate 720 near the solder bumps 760.

The spacer 770 may be arranged on the back surface of the semiconductor chip 730 corresponding to the second encapsulant 753.

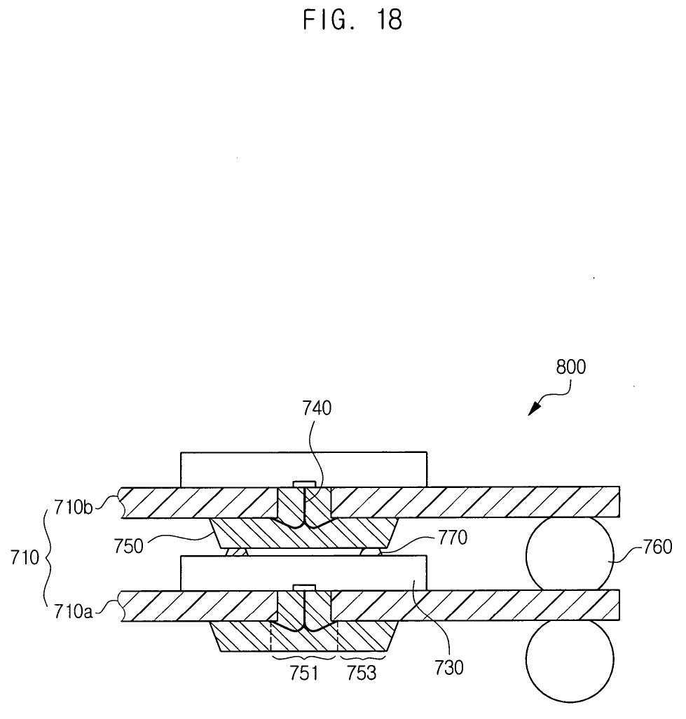

FIG. 18 is a cross-sectional view of a stack package 800 using the BOC package embodiments 710 illustrated in FIG. 17.

Referring to FIG. 18, the stack package 800 may comprise a lower package 710a and an upper package 710b stacked on the lower package 710a using the solder bumps 760.

The spacer 770 may be located near the encapsulant 750 of the upper package 710b. The upper package 710b may be stacked on the lower package 710a such that the spacer 770 may contact the second encapsulant 753. Therefore, the spacer 770 may prevent mechanical stresses from being applied to the bonding wires 740 in the first encapsulant 751.

The stack package 800 may have the same structure as the stack package 200 illustrated in FIG. 6, in that the spacer 770 may be arranged between the semiconductor chip 730 of the lower package 710a and the encapsulant 750 of the upper package 710b.

In accordance with the example embodiments of the present invention, the spacer may be provided between a semiconductor chip of a lower package and an encapsulant of an upper package. The spacer may sustain mechanical stresses applied to the encapsulant, thereby protecting bonding wires embedded in the encapsulant.

Although example, non-limiting embodiments of the present invention have been described in detail, it will be understood that many variations and/or modifications of the basic inventive concepts, which may appear to those skilled in the art, will still fall within the spirit and scope of the example embodiments of the present invention as defined in the appended claims.

What is claimed is:

1. A semiconductor package including:
a circuit substrate having a top surface, a bottom surface, and a central window;
a semiconductor chip provided on the top surface of the circuit substrate, the semiconductor chip having an active surface with chip pads exposed through the central window, and a back surface opposite to the active surface;
bonding wires connecting the chip pads of the semiconductor chip to the circuit substrate through the central window;
an encapsulant sealing the chip pads and the bonding wires;
solder bumps provided on the bottom surface of the circuit substrate outside the encapsulant; and
a spacer provided on opposing sides of the encapsulant and having a height greater than the height of the bonding wire from the bottom surface of the circuit substrate.

2. The package of claim 1, wherein the spacer is provided on the bottom surface of the circuit substrate outside the bonding wire.

3. The package of claim 2, wherein the spacer is formed integrally with the encapsulant and has a height greater than the height of the encapsulant from the bottom surface of the circuit substrate.

4. The package of claim 3, wherein the encapsulant includes long sides and short sides, and wherein the spacer is arranged along the long sides of the encapsulant.

5. The package of claim 4, wherein the spacer includes at least one bar shaped protrusion.

6. The package of claim 1, wherein the spacer is provided on the bottom surface of the circuit substrate along the opposing sides of the encapsulant, the spacer having a height greater than the height of the encapsulant from the bottom surface of the circuit substrate.

7. The package of claim 6, wherein the encapsulant includes long sides and short sides, and wherein the spacer includes at least one bar shaped protrusion arranged along the long sides of the encapsulant.

8. The package of claim 7, wherein the spacer is formed from a liquid molding compound or a nonconductive film.

9. The package of claim 1, wherein the spacer is provided on the back surface of the semiconductor chip corresponding to the opposing sides of the encapsulant, the spacer having a height greater than the height of the encapsulant from the bottom surface of the circuit substrate.

10. The package of claim 9, wherein the spacer includes at least one bar shaped protrusion.

11. The package of claim 10, wherein the spacer is formed from at least one of a liquid molding compound and a nonconductive film.

12. The package of claim 1, wherein the encapsulant includes a first encapsulant sealing the bonding wires and a second encapsulant formed integrally with the first encapsulant, and wherein the spacer is provided on the back surface of the semiconductor chip corresponding to the second encapsulant.

13. A stack package comprising a plurality of semiconductor packages including a lower semiconductor package and an upper semiconductor package, each semiconductor package including:
a circuit substrate having a top surface, a bottom surface, and a central window;
a semiconductor chip provided on the top surface of the circuit substrate, the semiconductor chip having an active surface with chip pads exposed through the central window, and a back surface opposite to the active surface;
bonding wires connecting the chip pads of the semiconductor chip to the circuit substrate through the central window;
an encapsulant sealing the chip pads and the bonding wires;
solder bumps provided on the bottom surface of the circuit substrate outside the encapsulant; and
a spacer provided along opposing sides of the encapsulant and having a height greater than the height of the bonding wire from the bottom surface of the circuit substrate,
wherein the spacer of the upper semiconductor package is in contact with the semiconductor chip of the lower semiconductor package.

14. The package of claim 13, wherein the spacer is provided on the bottom surface of the circuit substrate outside the bonding wire.

15. The package of claim 14, wherein the spacer is formed integrally with the encapsulant and has a height greater than the height of the encapsulant from the bottom surface of the circuit substrate.

16. The package of claim 15, wherein the encapsulant includes long sides and short sides, and wherein the spacer is arranged along the long sides of the encapsulant.

17. The package of claim 16, wherein the spacer includes at least one bar shaped protrusion.

18. The package of claim 13, wherein the spacer is provided on the bottom surface of the circuit substrate at the opposing sides of the encapsulant, having a height greater than the height of the encapsulant from the bottom surface of the circuit substrate.

19. The package of claim 18, wherein the encapsulant includes long sides and short sides, and wherein the spacer includes at least one bar shaped protrusion arranged along the long sides of the encapsulant.

20. The package of claim 19, wherein the spacer is formed from a liquid molding compound or a nonconductive film.

21. The package of claim 13, wherein the spacer is provided on the back surface of the semiconductor chip corresponding to the opposing sides of the encapsulant, the spacer having a height greater than the height of the encapsulant from the bottom surface of the circuit substrate.

22. The package of claim 21, wherein the spacer includes at least one bar shaped protrusion.

23. The package of claim 22, wherein the spacer is formed from at least one of a liquid molding compound and a nonconductive film.

24. The package of claim 13, wherein the encapsulant includes a first encapsulant sealing the bonding wires and a second encapsulant formed integrally with the first encapsulant, and the spacer is provided on the back surface of the semiconductor chip corresponding to the second encapsulant.

25. A method of manufacturing a semiconductor package, the method comprising:
providing a semiconductor chip on a top surface of a circuit substrate having the top surface, a bottom surface, and a central window, the semiconductor chip having an active surface with chip pads exposed through the central window, and a back surface opposite to the active surface;
connecting a bonding wire from the chip pads of the semiconductor chip to the circuit substrate through the central window;
forming an encapsulant on a portion of the bottom surface of the circuit substrate to seal the chip pads and the bonding wire;
forming solder bumps on the bottom surface of the circuit substrate outside the encapsulant; and
forming a spacer on opposing sides of the encapsulant, the spacer being formed to have a height greater than the height of the bonding wire from the bottom surface of the circuit substrate.

26. The method of claim 25, wherein the spacer is formed integrally with the encapsulant and has a height greater than the height of the encapsulant from the bottom surface of the circuit substrate.

27. The method of claim 25, wherein the spacer is provided on the bottom surface of the circuit substrate along the opposing sides of the encapsulant, the spacer having a height greater than the height of the encapsulant from the bottom surface of the circuit substrate.

28. The method of claim 25, wherein the spacer is provided on the back surface of the semiconductor chip corresponding to the opposing sides of the encapsulant, the spacer having a height greater than the height of the encapsulant from the bottom surface of the circuit substrate.
